(19) United States
(12) Patent Application Publication
(10) Pub. No.: US 2002/0179995 A1
(43) Pub. Date: Dec. 5, 2002

(54) Semiconductor component on an insulation layer

(76) Inventor: Wolfgang Werner, Munchen (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/158,026

(22) Filed: May 30, 2002

(30) Foreign Application Priority Data
May 30, 2001 (DE) 101 26 147.0

(51) Int. Cl. H01L 29/00

(52) U.S. Cl. 257/510

(57) ABSTRACT

A semiconductor component is described which is realized on an insulation layer and has a first zone of a first conductivity type, a second zone of the first conduction type, and a third zone of a second conductivity type. The third zone is formed between the first zone and the second zone. A heavily doped zone of the second conductivity type is formed adjacent to the first zone and forms a tunnel diode with the first zone.

### BACKGROUND OF THE INVENTION

1. Field of the Invention

The present invention relates to a semiconductor component. The semiconductor component contains a substrate, an insulation layer disposed on the substrate, a semiconductor layer disposed on the insulation layer, a first zone of a first conductivity type formed in the semiconductor layer, a second zone of the first conductivity type formed in the semiconductor layer, and a third zone of a second conductivity type formed in the semiconductor layer between the first zone and the second zone. A control electrode is disposed in a manner insulated from the semiconductor layer. The control electrode, when a drive potential is applied, brings about a conductive channel in the third zone between the first and second zones.

Such a semiconductor component, whose active regions are realized in the semiconductor layer on the insulation layer above the substrate, is generally known from the prior art.

The component functions as a MOS transistor, the first and second zones forming source and drain zones, respectively, the third zone forming a body zone or base zone and the control electrode forming a gate electrode of the transistor. In the case of an n-conducting transistor, the source and drain zones are heavily n-doped and the body zone is heavily p-doped and, in the case of a p-conducting transistor, the source and drain zones are p-doped and the body zone is n-doped. The gate electrode formed above the body zone in a manner insulated from the semiconductor layer enables the formation of a conductive channel in the body zone between the source zone and the drain zone, in order, when a voltage is applied between the source zone and drain zone, to enable a current flow between a source terminal and a drain terminal.

The semiconductor layer applied on the insulation layer is composed, in particular, of silicon; such components are then referred to as silicon on insulator (SOI) components. The term SOI component or SOI technology is used hereinafter synonymously for a component or a technology in which a semiconductor layer made of an arbitrary semiconductor material, for example including GaAs or SiC, is applied on an insulation layer.

The fabrication of the active regions of semiconductor components, in particular of diodes or transistors, in a semiconductor layer above an insulation layer affords the advantage that it is possible to realize a multiplicity of CMOS components next to one another, which can be insulated from one another in a simple manner. In addition to the insulation layer which insulates the component from the substrate, the insulation of adjacent components is effected either by forming trenches in the semiconductor layer which reach as far as the insulation layer, or by fabricating insulating zones, for example by oxidation, which likewise reach as far as the insulation layer.

Compared with so-called bulk CMOS processes, in which there is no insulation layer present on a substrate and in which individual components are insulated from one another by pn junctions in a known manner, a higher component density can be obtained in the case of components in SOI technology. Furthermore, the junction capacitance in the case of transistors in SOI technology is considerably reduced compared with the junction capacitance of transistors in bulk technology, which contributes to shorter switching times, so that SOI components are suitable in particular for high-frequency circuits.

By virtue of the sequence of the drain zone, the body zone complementary to the source and drain zones, and the drain zone, MOS transistors always contain a parasitic bipolar transistor whose base is formed by the body zone and whose collector/emitter is formed by the drain/source zone. When a voltage is applied between the drain and source and the gate electrode is not driven, charge carriers—holes in the case of n-conducting MOS transistors and electrons in the case of p-conducting MOS transistors—are injected into the body zone, or into the base of the parasitic bipolar transistor. The reverse current generated by the injected charge carriers is amplified by the parasitic bipolar transistor, in which case the current gain may amount to as much as 100 or more and a considerable quiescent current consumption of a circuit with a multiplicity of transistors can result from this.

In order to prevent the parasitic bipolar transistor from becoming active, it is common knowledge to short-circuit the source and the body of the transistor, which results in a reduction of the quiescent current consumption. However, the short-circuiting of the source and body is not employed in SOI components, since the realization of such a short circuit is space-consuming and would thereby invalidate the advantage of a higher component density in the case of components in SOI technology.

### SUMMARY OF THE INVENTION

It is accordingly an object of the invention to provide a semiconductor component on an insulation layer that overcomes the above-mentioned disadvantages of the prior art devices of this general type, which has a reduced quiescent current consumption.

With the foregoing and other objects in view there is provided, in accordance with the invention, a semiconductor component. The semiconductor component contains a substrate, an insulation layer disposed on the substrate, a semiconductor layer disposed on the insulation layer, a first zone of a first conductivity type formed in the semiconductor layer, a second zone of the first conductivity type formed in the semiconductor layer, and a third zone of a second conductivity type formed in the semiconductor layer between the first zone and the second zone. A control electrode is disposed in a manner insulated from the semiconductor layer. The control electrode, when a drive potential is applied, brings about a conductive channel in the third zone between the first and second zones. A fourth zone of the second conductivity type is disposed adjacent to the first zone and forms a tunnel diode with the first zone.

The semiconductor component has the substrate, the insulation layer disposed on the substrate, the semiconductor layer disposed on the insulation layer, and in the semiconductor layer the first and second zones of the first conductivity type, between which is disposed the third zone of the second conductivity type. The control electrode is formed in a manner insulated from the semiconductor layer, which control electrode, when a drive potential is applied, brings about a conductive channel in the third zone between the first and second zones. In the case of a MOS transistor, the first zone forms the source zone, the second zone forms the drain zone, the third zone forms body or base zone and the control electrode forms the gate electrode.

The invention provides the fourth zone of the second conductivity type, which adjoins the first zone or source zone and forms a tunnel diode with the source zone.

The doping concentrations of the source zone and of the fourth zone have approximately the same magnitude and are preferably more than 10²⁰ cm⁻³, in particular between 2·10₂₀ cm and 8·10₂₀ cm⁻³. In addition, the doping concentration of the second zone approximately corresponds to the doping concentration of the first zone.

In the semiconductor component according to the invention, the body zone is connected to the source zone via the tunnel diode formed from the source zone and the fourth zone of the same conductivity type as the body zone, in order thereby to reduce the current gain of the parasitic bipolar transistor formed from the source zone, the body zone and the drain zone, ideally in order to reduce the current gain of the parasitic bipolar transistor to one. The tunnel diode can be realized in a space-saving manner for example by forming the fourth zone below the source zone.

Other features which are considered as characteristic for the invention are set forth in the appended claims.

Although the invention is illustrated and described herein as embodied in a semiconductor component on an insulation layer, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, sectional view of an exemplary embodiment of a semiconductor component according to the invention; and

FIG. 2 is an electrical equivalent circuit diagram of the semiconductor component shown in FIG. 1.

### DESCRIPTION OF THE PREFERRED EMBODIMENTS

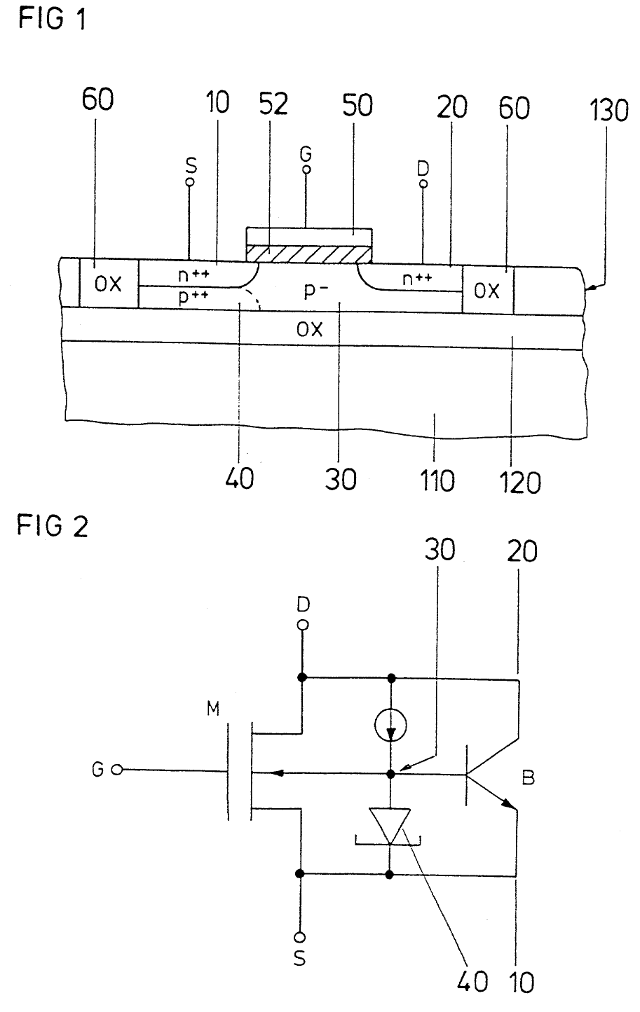

Referring now to the figures of the drawing in detail and first, particularly, to FIG. 1 thereof, there is shown an exemplary embodiment of a semiconductor component according to the invention in a side view in cross section. The semiconductor component has a substrate 110, on which an insulation layer 120 is applied. A semiconductor layer 130, in particular a monocrystalline semiconductor layer, is applied on the insulation layer 120.

The substrate 110 is likewise composed of a semiconductor material, for example.

In the semiconductor layer 130, a heavily n-doped source zone 10 is formed and a heavily n-doped drain zone 20 is formed in a manner spaced apart from the source zone 10 in a lateral direction, a p-doped body zone 30 being formed between the zones 10, 20. A gate electrode 50 is disposed above the semiconductor layer 130 in a manner insulated by an insulation layer 52, which gate electrode 50 extends in the lateral direction from the source zone 10 as far as the drain zone 20, and, when a drive potential is applied to the gate electrode 50 or a gate terminal G, a conductive channel is formed in the body zone 30 between the drain zone 20 and the source zone 10. The source zone 10 is connected to a source terminal S and the drain zone 20 is connected to a drain terminal D.

In the exemplary embodiment, below the source zone 10, a heavily p-doped zone 40 is provided between the insulation layer 120 and the source zone 10. A doping concentration of the zone 40 approximately corresponds to the doping concentration of the source zone 10 and the zone 40 is doped significantly more highly than the rest of the body zone 30. The zone 40 forms, together with the source zone 10, a tunnel diode via which the body zone 30 is connected to the source zone 10 or the source terminal S. The tunnel diode is electrically connected in parallel with a pn junction, formed below the gate electrode 50, between the body zone 30 and the source zone 10.

The source zone 10, the body zone 30 and the drain zone 20 form a parasitic bipolar transistor whose base is formed by the body zone 30, whose emitter is formed by the source zone 10 and whose collector is formed by the drain zone 20. When a voltage is applied between the drain terminal D and the source terminal S, in the case of the n-conducting transistor illustrated, holes are injected into the body zone 30 or the base of the parasitic bipolar transistor, the charge carriers being dissipated to the source terminal S via the tunnel diode formed from the zone 40 and the source zone 10, which prevents the parasitic bipolar transistor from being activated or which reduces the current gain of the parasitic bipolar transistor to one. Compared with conventional components of this type, the quiescent current consumption of the MOS transistor with tunnel diode as illustrated in FIG. 1 is considerably reduced, namely by the factor of the current gain of the parasitic bipolar transistor in conventional components.

FIG. 2 shows the electrical equivalent circuit diagram of the semiconductor component illustrated in FIG. 1. As already mentioned, the component contains, in addition to the actual MOS transistor M formed by the source zone 10, the body zone 30, the drain zone 20 and the gate electrode 50, a parasitic bipolar transistor B formed by the source zone 10, the body zone 30 and the drain zone 20. The collector of the parasitic bipolar transistor B is formed by the drain zone 20 and the emitter is formed by the source zone 10, which, in the equivalent circuit diagram, corresponds to the collector-emitter path of the bipolar transistor B connected in parallel with the drain-source path of the MOS transistor M. Between the drain terminal D and the body zone 30 or the base of the parasitic bipolar transistor B, a current source is depicted in the circuit diagram, which current source, when a voltage is applied between the drain D and source S, injects charge carriers into the body zone 30 or the base of the parasitic bipolar transistor B. The tunnel diode formed from the zone 40 and the source zone 10 is connected between the body zone or the base of the parasitic bipolar transistor B and the source zone 10 or the emitter of the parasitic bipolar transistor, which tunnel diode dissipates the base current of the parasitic bipolar transistor B in order to reduce the current gain of the parasitic bipolar transistor to one.

FIG. 1 shows an n-conducting MOS transistor. It goes without saying that the invention is not restricted to n-conducting MOS transistors, but rather can also be applied to p-conducting transistors, in which case the n-doped regions in FIG. 1 are to be replaced by p-doped regions and the p-doped regions in FIG. 1 are to be replaced by n-doped regions.

I claim:

1. A semiconductor component, comprising:
a substrate;
an insulation layer disposed on said substrate;
a semiconductor layer disposed on said insulation layer;
a first zone of a first conductivity type formed in said semiconductor layer;
a second zone of said first conductivity type formed in said semiconductor layer;
a third zone of a second conductivity type formed in said semiconductor layer between said first zone and said second zone;
a control electrode disposed in a manner insulated from said semiconductor layer, said control electrode, when a drive potential is applied, brings about a conductive channel in said third zone between said first and second zones; and
a fourth zone of said second conductivity type disposed adjacent to said first zone and forms a tunnel diode with said first zone.

2. The semiconductor component according to claim 1, wherein said first zone has a doping concentration substantially corresponding to a doping concentration of said fourth zone.

3. The semiconductor component according to claim 1, wherein said first zone and said fourth zone each have a doping concentration greater than 1020 cm⁻³.

4. The semiconductor component according to claim 1, wherein said first zone and said fourth zone each have a doping concentration between 2·10 cm⁻¹ and 8·10²⁰ cm⁻³.

5. The semiconductor component according to claim 1, wherein said second zone has a doping concentration substantially corresponding to a doping concentration of said first zone.
